(19) United States
(12) Patent Application Publication
(10) Pub. No.: US 2008/0111555 A1
(43) Pub. Date: May 15, 2008

(54) Security system controller with integrated tester

(75) Inventors: Arturas Rainys, Vista, CA (US); Wallace Stewart, Vista, CA (US)

Correspondence Address: DIRECTED ELECTRONICS, INC., 1 VIPER WAY, VISTA, CA, 92061, US

(73) Assignee: DEI Headquarters Inc.

(21) Appl. No.: 11/600,367

(22) Filed: Nov. 15, 2006

(51) Int. Cl. F02P 17/00; G01R 3/00; G01R 1/00

(52) U.S. Cl. 324/380; 324/149; 324/157

(57) ABSTRACT

A controller is provided for use with a vehicle security system, particularly a remote start system. The controller includes a housing, means for detecting voltage of a vehicle wire, and means for displaying detected voltage. The means for detecting voltage can be an external probe. The means for displaying detected voltage can be a light indicator, a sound indicator, or a display screen. If a light indicator is used, such as an LED, the light indicator can emit different colors of light responsive to different voltages detected. If a sound indicator is used, the sound indicator emits different pitched sound tones or a different number of sound tones based on different voltages detected. The controller can include a means for detecting resistance of a wire and a switch for changing between detecting voltage and resistance. The controller can include a switch for changing between different detection states.

### FIELD OF THE INVENTION

The present invention relates generally to security systems, and, more particularly, to security systems installed in automobiles.

### BACKGROUND

Security and alarm systems are well-known. A security system may be used to secure a perimeter or an object against theft, tampering, vandalism, invasion, unauthorized use or access, and other kinds of trespass. The secured object or perimeter may be, for example, a vehicle or a building, protected by sensors capable of detecting glass-break events; proximity or movement of a person; openings of doors, trunk, or hood; and other potential breaches of security. A typical security system designed for automotive applications is capable of responding to breaches of security, for example, by activating an alarm and rendering engine starter and engine computer systems inoperative. In addition, some security systems can control various safety and convenience features, such as power door locks, power windows, and entertainment system installed in the vehicle.

Some vehicle security systems provide for remote starting capabilities. A remote vehicle starter is a device which allows an operator to start a vehicle without having to turn the ignition key. Remote starting of a vehicle is most often achieved through use of a remote control transmitter. In a typical use, an operator of a vehicle will remotely start the vehicle on a cold day to allow the vehicle's engine to reach normal operating temperature prior to the operator entering the vehicle, as the operator would normally have to wait several minutes for a vehicle's engine to reach normal operating temperature otherwise. A remote vehicle starter can be used in other situations to provide convenience and time-saving opportunity to a vehicle operator.

Generally, remote start vehicle systems can be difficult to install. Remote start systems need to be hooked up to a large number of wires in a variety of different locations under the dash and under the hood of a car. The color of each wire is different from car to car—and even from year to year with the same make and model of the car. Remote starters contain anywhere from 8 to 15 wires that must be integrated with the wiring of the car. Additional wiring, extra fuses, tachometer sensing devices, relays, and often a separate remote control radio receiver unit must also be installed. As each car's wiring system and wiring colors are unique, it can be difficult for even the most professional installers to ensure that the unit is being installed correctly. The entire installation process can take up to several hours even if completed by an experienced professional.

Although some remote start vehicle systems can be difficult to install, some systems are specifically designed for installation by the consumer. These systems are often referred to as “do-it-yourself” (DIY) systems. DIY remote start systems are typically less complex than the traditional remote start vehicle systems that must be installed by a professional, thus allowing a typical consumer the ability to install the system without needing to consult a trained professional. DIY systems are useful in that they save the consumer the time and effort needed to select and have a professional install the system in one's vehicle. Further, DIY remote start systems can also save the consumer money compared to the more complex professionally installed remote start vehicle systems.

While DIY remote start vehicle systems provide some advantages, there are also a few disadvantages. Primarily, the consumer must have a basic knowledge of electronics and be familiar with the tools necessary to install the system. Secondly, the consumer must possess all of the tools required to complete the system installation. If the consumer does not possess the required tools, and does not have easy access to such tools, the consumer must then purchase the necessary tools in order to properly install the system in a vehicle. While the tools may have some use to the consumer outside of the remote start system installation procedure, if a consumer must purchase additional tools to perform an installation, the cost-saving benefit a consumer achieves from purchasing a DIY remote start vehicle system will be severely diminished or eliminated altogether.

One of the main steps involved in installing a remote start vehicle system is for the installer to identify specific vehicle circuits that are involved in the installation process, such as circuits for the ignition, accessory, parking lights, and the brake wire. It is necessary for the remote start security controller to be properly connected to the various wiring to prevent damage to the controller and the vehicle's electrical system. A volt-meter or multi-meter is traditionally used to detect the voltage of the various wires in the vehicle. These tools are generally known in the art. However, many consumers do not have a voltmeter or multi-meter, as they can be expensive to purchase. Thus, because identifying the proper wires is an important step in the installation process and cannot be skipped, if a consumer that does not already have a voltage tester available desires to install a DIY remote start vehicle system, the consumer will have to purchase the voltage tester equipment and will not be able to realize the cost-saving benefit provided by DIY remote start systems.

Currently, there are no DIY remote start vehicle systems that provide a built-in mechanism that allows a consumer to detect the proper electrical wires during remote start system installation. Therefore, it would be highly desirable to provide a DIY remote start vehicle system having integrated voltage testing capabilities.

### SUMMARY

The preferred embodiment of the present invention involves a controller for use with a remote start security system for installation in a vehicle. The controller includes a housing, means for detecting voltage, and means for displaying detected voltage. During the installation of the remote start security system, a user can use the means for detecting voltage to determine the voltage of vehicle wiring. Preferably, the means for detecting voltage is an external probe that can be removably attached to the housing. The means for displaying detected voltage can be a light indicator, a sound indicator, or a display screen. If a light indicator is used, such as a light emitting diode, the light indicator can emit different colors of light in response to the detection of different voltages, including different voltage polarity. If a sound indicator is used, the sound indicator emits different pitched sound tones or a different number of sound tones based on the detection of different voltages, including different voltage polarity.

Another embodiment of the present invention involves a controller for use with a remote start security system for installation in a vehicle. The controller includes a housing, means for detecting resistance, and means for displaying detected resistance. During the installation of the remote start security system, a user can use the means for detecting resistance to determine the resistance of vehicle wiring. Preferably, the means for detecting resistance is an external probe that can be removably attached to the housing. The means for displaying detected resistance can be a light indicator, a sound indicator, or a display screen. If a light indicator is used, such as a light emitting diode, the light indicator can emit different colors of light in response to the detection of different resistances. If a sound indicator is used, the sound indicator emits different pitched sound tones or a different number of sound tones based on the detection of different resistances.

Another embodiment of the present invention involves a controller for use with a remote start security system for installation in a vehicle. The controller includes a housing, means for detecting voltage and resistance, and means for displaying detected voltage and resistance. During the installation of the remote start security system, a user can use the means for detecting voltage and resistance to determine the voltage and resistance of vehicle wiring. Preferably, the means for detecting voltage and resistance is an external probe that can be removably attached to the housing. The means for displaying detected voltage and resistance can be a light indicator, a sound indicator, or a display screen. If a light indicator is used, such as a light emitting diode, the light indicator can emit different colors of light in response to the detection of different voltages, including different voltage polarity, and resistances. If a sound indicator is used, the sound indicator emits different pitched sound tones or a different number of sound tones based on the detection of different voltages or resistances. The controller also includes a switch attached to the housing. The switch can be configured to allow a user to change between detection states, such as between detecting voltage and detecting resistance of the wiring, or between detecting power wires and ground wires.

A further embodiment of the present invention involves a controller for use with a remote start security system for installation in a vehicle. The controller includes a housing, an external probe for detecting positive and negative voltage, means for displaying detected voltage, and a switch for selecting between the testing of positive voltages and the testing of negative voltages. The means for displaying detected voltage can be a light indicator, a sound indicator, or a display screen. If a light indicator is used, such as a light emitting diode, the light indicator can emit different colors of light in response to the detection of different voltages, including different voltage polarity. If a sound indicator is used, the sound indicator emits different pitched sound tones or a different number of sound tones based on the detection of different voltages, including different voltage polarity. During the installation of the remote start security system, a user can use the switch to choose between detecting positive voltages and negative voltages. The user can then use the external probe to determine the voltage of a vehicle wire, with the voltage being displayed on the means for displaying detected voltage.

These and other features and aspects of the present invention will be better understood with reference to the following description, drawings, and appended claims.

### BRIEF DESCRIPTION OF THE FIGURES

FIG. 1 is a block diagram of the preferred embodiment of the remote start security system controller with integrated tester.

FIG. 2 is a block diagram of another embodiment of the remote start security system controller with integrated tester.

FIG. 3 is a block diagram of yet another embodiment of the remote start security system controller with integrated tester.

FIG. 4 is a block diagram of still another embodiment of the remote start security system controller with integrated tester.

FIG. 5 is a front perspective view of the preferred embodiment of the remote start security system controller with integrated tester.

FIG. 6 is a front perspective view of another embodiment of the remote start security system controller with integrated tester.

FIG. 7 is a front perspective view of yet another embodiment of the remote start security system controller with integrated tester.

FIG. 8 is a front perspective view of still another embodiment of the remote start security system controller with integrated tester.

### DETAILED DESCRIPTION

Reference will now be made in detail to several embodiments of the invention that are illustrated in the accompanying drawings. Wherever possible, same or similar reference numerals are used in the drawings and the description to refer to the same or like parts. The drawings are in a simplified form and are not to precise scale. For purposes of convenience and clarity only, directional terms, such as, top, bottom, left, right, up, down, over, above, below, beneath, rear, and front, may be used with respect to the accompanying drawings. These and similar directional terms should not be construed to limit the scope of the invention in any manner.

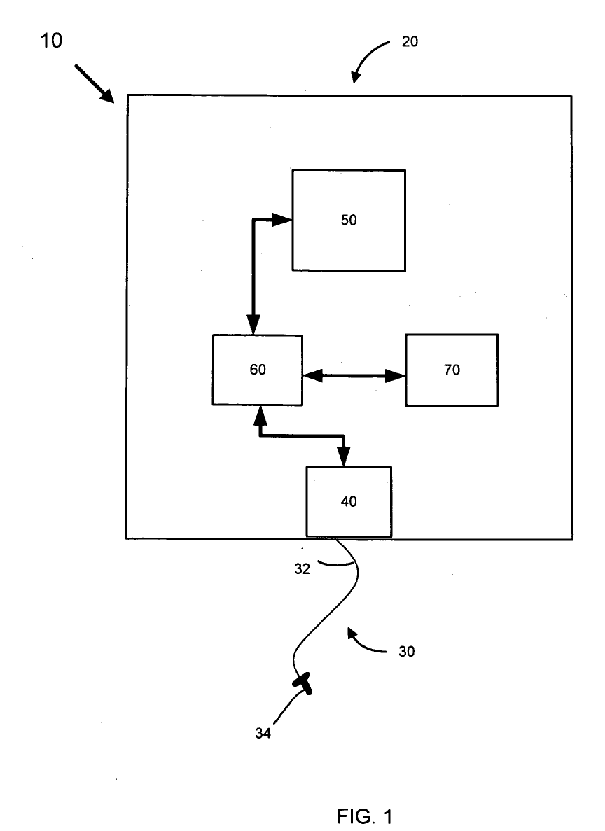

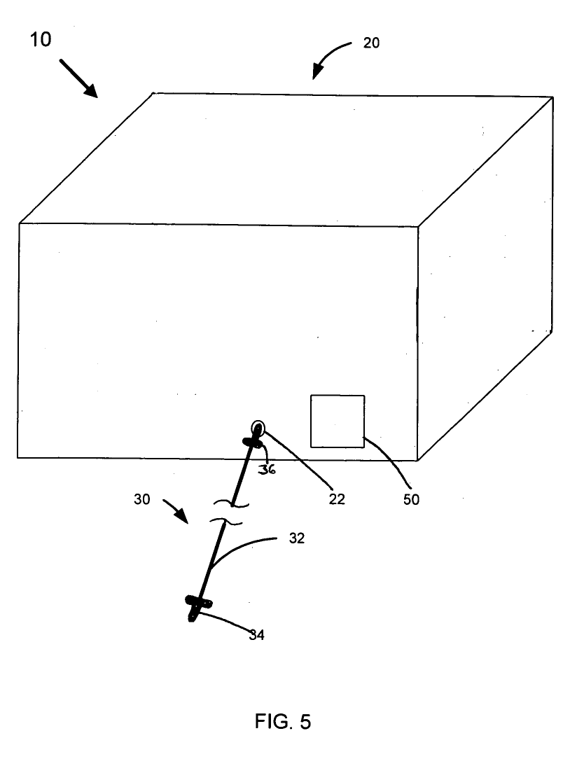

Referring more particularly to the drawings, FIG. 1 illustrates a block diagram of the preferred embodiment of the remote start security system controller with integrated tester 10. Controller 10 includes a housing 20, an external probe 30, probe interface 40, and an indicator 50. Probe 30 includes a flexible conductor 32, a tip 34, and a connector 36 (see FIG. 5). Tip 34 is used to measure the voltage of the battery. The connector is plugged into housing 20 to interface with probe interface 40. Flexible conductor 32 can be comprised of a conducting wire enclosed by non-conductive material, as is recognized in the art. Interface 40 can comprise circuitry for detecting voltages or can comprise leads for passing the detected voltages directly to processor 60. Controller 10 can also include a processor 60 and memory 70. Processor 60 is used to determine voltage and generate output to appear on indicator 50. Memory 70 can be used to store the detected voltage and the programming for processor 60. Memory 70 can comprise RAM, ROM, PROM, EPROM, EEPROM, flash memory, or other memory types as recognized in the art. Memory 70 can comprise one or more memory modules.

Indicator 50 can comprise a light indicator, a sound indicator, or a display screen. If a light indicator is used, such as a light emitting diode, incandescent light bulb, or fluorescent light, the light indicator can emit different colors of light in response to the detection of different voltages. For example, if a voltage of 6V is detected, which can correspond to a low voltage level, the light indicator can emit a yellow light. If a voltage of 12V is detected, which can correspond to a normal voltage, the light indicator can emit a green light. If no voltage is detected, the light indicator can emit a red light. In a similar manner, if a sound indicator is used, the sound indicator emits different pitched sound tones or a different number of sound tones based on the detection of different voltages. For example, if a voltage of 6V is detected, which can correspond to a low voltage level, the sound indicator can emit a medium frequency sound. If a voltage of 12V is detected, which can correspond to a normal voltage, the sound indicator can emit a high frequency sound. If a negative voltage is detected, the sound indicator can emit a low frequency sound. Similarly, if voltage of 6V is detected, which can correspond to a low voltage level, the sound indicator can emit one sound tone. If a voltage of 12V is detected, which can correspond to a normal voltage, the sound indicator can emit two sound tones. If a negative voltage is detected, the sound indicator can emit three sound tones. A user guide can be included with tester 10 to help the user correlate the audio or visual output of indicator 50 to particular values or ranges of values.

For illustration purposes, the use of controller 10 will be discussed with regard to its conjunction with a remote start security system. However, it is to be recognized that controller 10 can be used with other security systems that do not have remote start capabilities, including systems that are not DIY systems. To use controller 10, a user first connects the ground wire of controller 10 (not shown) to the chassis of the vehicle (not shown). The user then plugs external probe 30 into housing 20 or probe interface 40. The user can then use tip 34 to identify a 12V or 24V source, such as an ignition switch. Once this source is identified, the user can connect the main power wire of controller 10 (not shown) to the source. When this occurs, controller 10 will have a reference voltage source. The user can then use tip 34 to contact a vehicle wire. As this occurs, probe interface 40 will detect the voltage of the wire and send the voltage signal to processor 60. Processor 60 then processes the voltage signal by comparing the detected voltage to the reference voltage source, and sends a corresponding output representing the voltage difference between the controller and the wire to indicator 50, wherein indicator 50 outputs an indication to the user. The user can then use the indication to identify the wire and connect the wire to the proper connection point on controller 10.

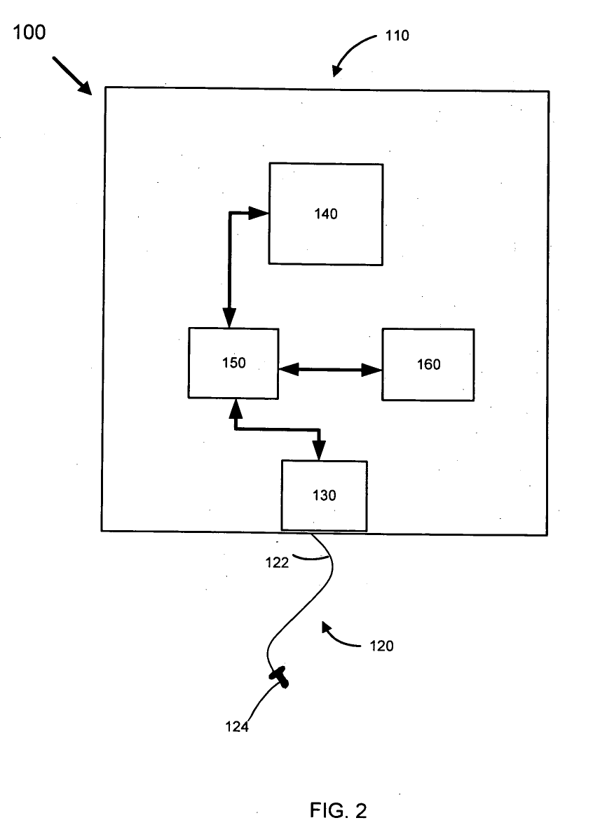

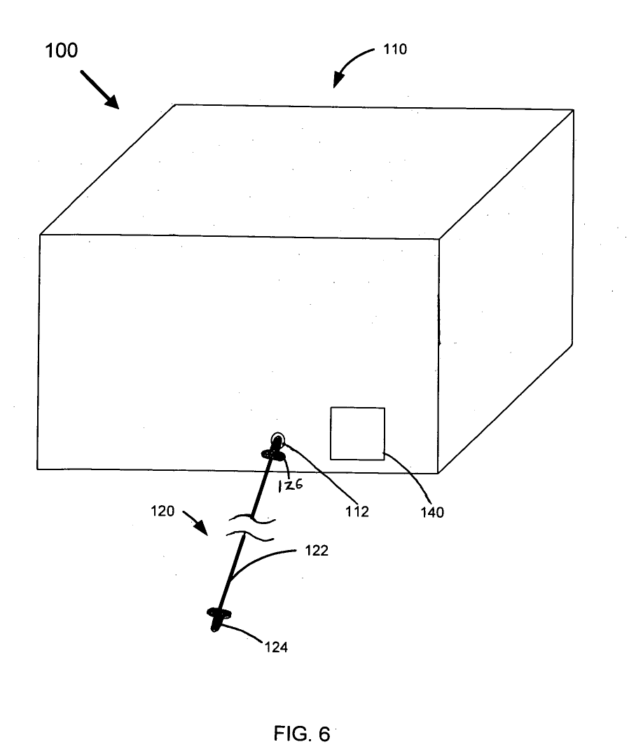

FIG. 2 illustrates a block diagram of another embodiment of the remote start security system controller with integrated tester 100. Controller 100 includes a housing 110, an external probe 120, probe interface 130, and an indicator 140. Probe 120 includes a flexible wire 122, a tip 124, and a connector 126 (see FIG. 6). Tip 124 is used to measure the resistance of a vehicle wire. The connector is plugged into housing 110 to interface with probe interface 130. Interface 130 can comprise circuitry for detecting resistances or can comprise leads for passing the detected resistances directly to processor 150. Controller 110 can also include a processor 150 and memory 160. Processor 150 is used to determine resistance and generate output to appear on indicator 140. Memory 160 can be used to store the detected resistance and the programming for processor 150. Memory 160 can comprise RAM, ROM, PROM, EPROM, EEPROM, flash memory, or other memory types as recognized in the art. Memory 160 can comprise one or more memory modules.

Indicator 140 can comprise a light indicator, a sound indicator, or a display screen. If a light indicator is used, preferably a liquid crystal display screen, the resistance value can be displayed on the screen. However, if the light indicator is a light device, such as a light emitting diode, incandescent light bulb, or fluorescent light, the light indicator can emit different colors of light in response to the detection of different resistances. For example, if a low resistance level is detected, the light indicator can emit a yellow light. If a high resistance level is detected, the light indicator can emit a green light. If no resistance is detected, indicating a short circuit, the light indicator can emit a red light. In a similar manner, if a sound indicator is used, the sound indicator can emit different pitched sound tones or a different number of sound tones based on the detection of different resistances. For example, if a low resistance is detected, the sound indicator can emit a medium frequency sound. If a high resistance is detected, the sound indicator can emit a high frequency sound. If no resistance is detected, indicating a short circuit, the sound indicator can emit a low frequency sound. Similarly, if a low resistance is detected, the sound indicator can emit one sound tone, if a high resistance is detected, the sound indicator can emit two sound tones, and if no resistance is detected, indicating a short circuit, the sound indicator can emit three sound tones. A user guide can be included with tester 100 to help the user correlate the audio or visual output of indicator 140 to particular values or ranges of values.

For illustration purposes, the use of controller 100 will be discussed with regard to its conjunction with a remote start security system. However, it is to be recognized that controller 100 can be used with other security systems that do not have remote start capabilities, including systems that are not DIY systems. To use controller 100, a user first connects the ground wire of controller 100 (not shown) to the chassis of the vehicle (not shown). The user then plugs external probe 120 into housing 110. The user can then use tip 124 to identify a source of resistance, such as an ignition switch. Once this source is identified, the user can connect the main power wire of controller 100 (not shown) to the source. When this occurs, controller 100 will have a resistance reference. The user can then use tip 124 to contact a vehicle wire. As this occurs, probe interface 130 will detect the resistance of the wire and send the signal to processor 150. Processor 150 then processes the signal by comparing the detected resistance to the reference resistance, and sends a corresponding output representing the difference in resistance between the controller and the wire to indicator 140, wherein indicator 140 outputs an indication to the user. The user can then use the indication to identify the wire and connect the wire to the proper connection point on controller 100.

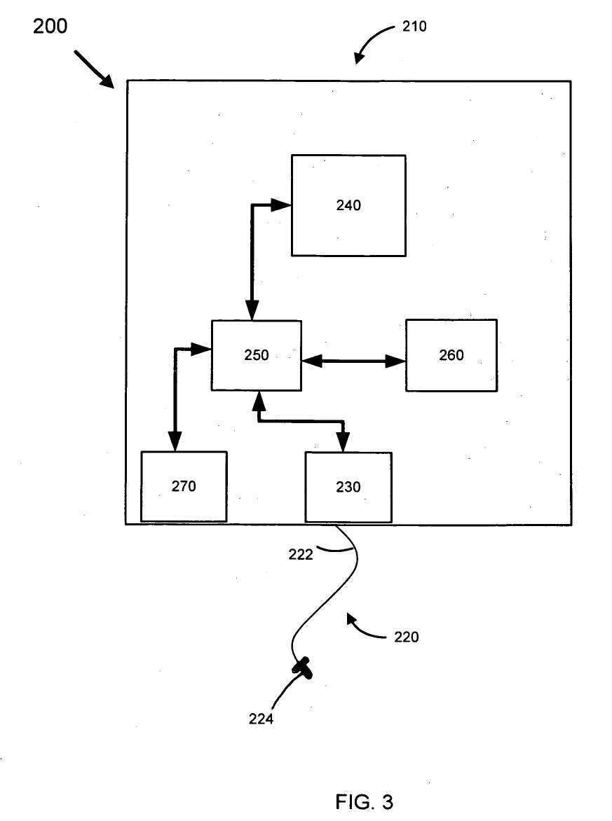

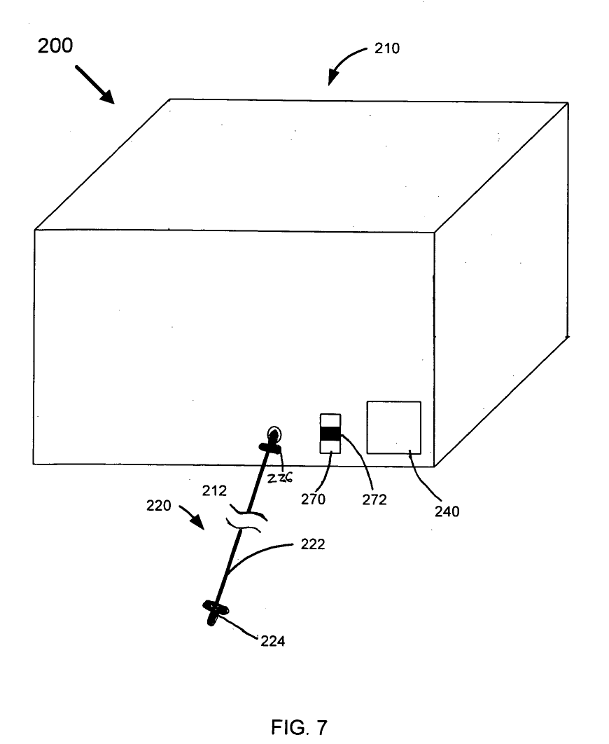

FIG. 3 illustrates a block diagram of still another embodiment of the remote start security system controller with integrated tester 200. Controller 200 includes a housing 210, an external probe 220, probe interface 230, and an indicator 240. Probe 220 includes a flexible wire 222, a tip 224, and a connector 226 (see FIG. 7). Tip 224 is used to measure either the voltage of the vehicle wires or the resistance of the vehicle wires. The connector is plugged into housing 210 to interface with probe interface 230. Interface 230 can comprise circuitry for detecting voltages and resistances or can comprise leads for passing the detected voltages and resistances directly to processor 250. Controller 210 can also include a processor 250 and memory 260. Processor 250 is used to determine wire voltage and wire resistance and generate output to appear on indicator 240. Memory 260 can be used to store the detected voltage and the programming for processor 250. Memory 260 can comprise RAM, ROM, PROM, EPROM, EEPROM, flash memory, or other memory types as recognized in the art. Memory 260 can comprise one or more memory modules. Controller 200 also includes a switch 270 that allows a user to manually change between different detection states, such as testing voltage and testing resistance. Switch 270 can be a toggle switch, button, lever, or other switch device as recognized in the art.

Indicator 240 can comprise a light indicator, a sound indicator, or a display screen. If a light indicator is used, preferably a liquid crystal display screen, the voltage value can be displayed on the screen. However, if the light indicator is a light device, such as a such as a light emitting diode, incandescent light bulb, or fluorescent light, the light indicator can emit different colors of light in response to the detection of different voltages or resistances. For example, if a voltage of 6V were detected, which can correspond to a low voltage level, the light indicator can emit a yellow light. If a voltage of 12V were detected, which can correspond to a normal voltage, the light indicator can emit a green light. If a negative voltage is detected, the light indicator can emit a red light. In a similar manner, if a sound indicator is used, the sound indicator can emit different pitched sound tones or a different number of sound tones based on the detection of different voltages. For example, if a voltage of 6V were detected, which can correspond to a low voltage level, the sound indicator can emit a medium frequency sound. If a voltage of 12V were detected, which can correspond to a normal voltage, the light indicator can emit a high frequency sound. If a negative voltage is detected, the light indicator can emit a low frequency sound. Similarly, if voltage of 6V is detected, which can correspond to a low voltage level, the sound indicator can emit one sound tone. If a voltage of 12V is detected, which can correspond to a normal voltage, the sound indicator can emit two sound tones. If a negative voltage is detected, the sound indicator can emit three sound tones. A user guide can be included with tester 200 to help the user correlate the audio or visual output of indicator 240 to particular values or ranges of values.

For illustration purposes, the use of controller 200 will be discussed with regard to its conjunction with a remote start security system. However, it is to be recognized that controller 200 can be used with other security systems that do not have remote start capabilities, including systems that are not DIY systems. To use controller 200, a user first connects the ground wire of controller 200 (not shown) to the chassis of the vehicle (not shown). The user then plugs external probe 220 into housing 210. The user can then use tip 224 to identify a 12V or 24V source, such as an ignition switch. Once this source is identified, the user can connect the main power wire of controller 200 (not shown) to the source. When this occurs, controller 200 will have a voltage reference. The user can then use tip 224 to contact a vehicle wire. As this occurs, probe interface 230 will detect the voltage of the wire and send the voltage signal to processor 250. Processor 250 then processes the voltage signal by comparing the detected voltage to the reference voltage of either 12V or 24V, and sends a corresponding output representing the difference in resistance between the controller and the wire to indicator 240, wherein indicator 240 outputs an indication to the user. The user can then use the indication to identify the wire and connect the wire to the proper connection point on controller 200.

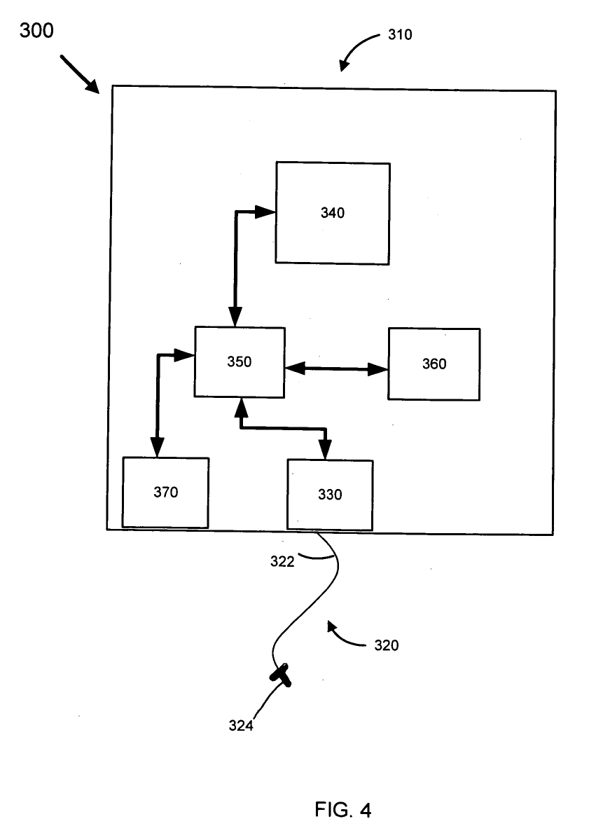

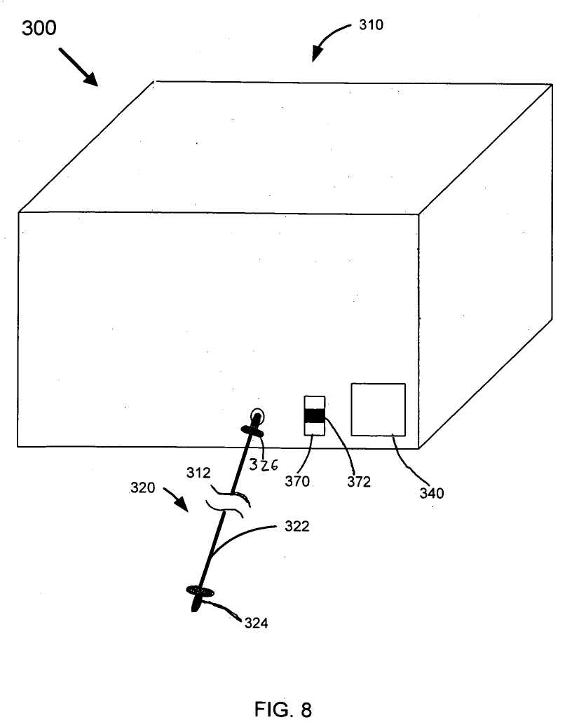

FIG. 4 illustrates a block diagram of still another embodiment of the remote start security system controller with integrated tester 300. Controller 300 includes a housing 310, an external probe 320, probe interface 330, and an indicator 340. Probe 320 includes a flexible wire 322, a tip 324, and a connector 326 (see FIG. 8). Tip 324 is used to measure either the voltage of the vehicle wires. The connector is plugged into housing 310 to interface with probe interface 330. Interface 330 can comprise circuitry for detecting positive and negative voltages or can comprise leads for passing the detected voltages directly to processor 350. Controller 310 can also include a processor 350 and memory 360. Processor 350 is used to determine wire voltage and generate output to appear on indicator 340. Memory 360 can be used to store the detected voltage and the programming for processor 350. Memory 360 can comprise RAM, ROM, PROM, EPROM, EEPROM, flash memory, or other memory types as recognized in the art. Memory 360 can comprise one or more memory modules. Controller 300 also includes a switch 370 that allows a user to manually change between detection states, such as testing either positive or negative voltages. Switch 370 can be a toggle switch, button, lever, or other switch device as recognized in the art.

Indicator 340 can comprise a light indicator, a sound indicator, or a display screen. If a light indicator is used, preferably a liquid crystal display screen, the voltage value can be displayed on the screen. However, if the light indicator is a light device, such as a such as a light emitting diode, incandescent light bulb, or fluorescent light, the light indicator can emit different colors of light in response to the detection of different voltages or resistances. For example, if a voltage of 6V were detected, which can correspond to a low voltage level, the light indicator can emit a yellow light. If a voltage of 12V were detected, which can correspond to a normal voltage, the light indicator can emit a green light. If a negative voltage is detected, the light indicator can emit a red light. In a similar manner, if a sound indicator is used, the sound indicator can emit different sound tones based on the detection of different voltages. For example, if a voltage of 6V were detected, which can correspond to a low voltage level, the sound indicator can emit a medium frequency sound. If a voltage of 12V were detected, which can correspond to a normal voltage, the sound indicator can emit a high frequency sound. If a negative voltage is detected, the sound indicator can emit a low frequency sound. Similarly, if voltage of 6V is detected, which can correspond to a low voltage level, the sound indicator can emit one sound tone. If a voltage of 12V is detected, which can correspond to a normal voltage, the sound indicator can emit two sound tones. If a negative voltage is detected, the sound indicator can emit three sound tones. A user guide can be included with tester 300 to help the user correlate the audio or visual output of indicator 340 to particular values or ranges of values.

For illustration purposes, the use of controller 300 will be discussed with regard to its conjunction with a remote start security system. However, it is to be recognized that controller 300 can be used with other security systems that do not have remote start capabilities, including systems that are not DIY systems. To use controller 300, a user first connects the ground wire of controller 300 (not shown) to the chassis of the vehicle (not shown). The user then plugs external probe 320 into housing 310. The user can then use tip 324 to identify a 12V or 24V source, such as an ignition switch. Once this source is identified, the user can connect the main power wire of controller 300 (not shown) to the source. When this occurs, controller 300 will have a voltage reference. The user can then use tip 324 to contact a vehicle wire. As this occurs, probe interface 330 will detect the voltage of the wire and send the voltage signal to processor 350. Processor 350 then processes the voltage signal by comparing the detected voltage to the reference voltage of either 12V or 24V, and sends a corresponding output representing the difference in resistance between the controller and the wire to indicator 340, wherein indicator 340 outputs an indication to the user. The user can then use the indication to identify the wire and connect the wire to the proper connection point on controller 300.

FIG. 5 illustrates a front perspective view of controller 10 as described herein. Controller includes a housing 20, external probe 30, and indicator 50. As shown, indicator 50 is a display screen, preferably a liquid crystal display. External probe 30 includes a connector 36 for connecting external probe 30 to housing 20 via connector port 22. Connector 36 can vary in size and shape depending on the size and shape of connector port 22.

FIG. 6 illustrates a front perspective view of controller 100 as described herein. Controller includes a housing 110, external probe 120, and indicator 140. As shown, indicator 140 is a display screen, preferably a liquid crystal display. However, indicator 140 can also be other types of display as recognized in the art. External probe 120 includes a connector 126 for connecting external probe 120 to housing 110 via connector port 112. Connector 126 can vary in size and shape depending on the size and shape of connector port 112.

FIG. 7 illustrates a front perspective view of controller 200 as described herein. Controller includes a housing 210, external probe 220, and indicator 240. As shown, indicator 240 is a display screen, preferably a liquid crystal display. However, indicator 240 can also be other types of display as recognized in the art. External probe 220 includes a connector 226 for connecting external probe 220 to housing 210 via connector port 212. Connector 226 can vary in size and shape depending on the size and shape of connector port 212. Controller further includes a switch 270 attached to housing 210. Switch 270 can be a toggle switch, button, lever, or other switch device as recognized in the art. As shown, switch 270 contains a toggle 272. Switch 270 can allow a user to change the function of controller 220 to change between detection states, such as between detecting voltage and detecting resistance of the wiring, or between detecting power wires and ground wires.

FIG. 8 illustrates a front perspective view of controller 300 as described herein. Controller includes a housing 310, external probe 320, and indicator 340. As shown, indicator 340 is a light indicator, preferably a light emitting diode. External probe 320 includes a connector 326 for connecting external probe 320 to housing 310 via connector port 312. Connector 326 can vary in size and shape depending on the size and shape of connector port 312. Controller further includes a switch 370 attached to housing 310. Switch 370 can be a toggle switch, button, lever, or other switch device as recognized in the art. As shown, switch 370 contains a toggle 372 that allows a user to change the function of controller 300 to change between detection states, such as between detecting voltage and detecting resistance of the wiring, or between detecting power wires and ground wires. The ability to switch between detecting states allows for the use of a simple indicator 340, such as a light indicator, rather than a display screen, which can be more costly. Nonetheless, in other embodiments, indicator 340 can also be a display screen or an audio speaker.

Although the preferred embodiments of this invention have been disclosed herein, the inventions may be embodied in other specific forms without department from the essential characteristics described in herein. Neither the specific embodiments of the invention as a whole, nor those of its features limit the general principles underlying the invention. The specific features described herein may be used in some embodiments, but not in others, without departure from the spirit and scope of the invention as set forth. Various physical arrangements of components and various step sequences also fall within the intended scope of the invention. Furthermore, the invention need not be limited to automotive or vehicular applications, but may extend to applications involving other kinds of security systems. Many additional modifications are intended in the foregoing disclosure, and it will be appreciated by those of ordinary skill in the art that in some instances some features of the invention will be employed in the absence of a corresponding use of other features. The illustrative examples therefore do not define the metes and bounds of the invention and the legal protection afforded the invention, which function is carried out by the claims and their equivalents.

I claim:

1. A controller for use with security systems for installation in a vehicle, including remote start security systems, the controller comprising:
a) a housing;
b) means for detecting voltage coupled to the housing; and
c) means for displaying detected voltage coupled to the housing
wherein during the installation of the remote start security system, a user can use the means for detecting voltage to determine the voltage of a vehicle wire, the voltage being displayed on the means for displaying detected voltage.

2. The controller of claim 1, wherein means for detecting voltage is an external probe.

3. The controller of claim 2, wherein the external probe is removably coupled to the housing.

4. The controller of claim 1, wherein the means for displaying detected voltage is a light indicator.

5. The controller of claim 4, wherein the light indicator is a light emitting diode.

6. The controller of claim 4, wherein the light indicator emits different colors of light based on different detected voltages.

7. The controller of claim 1, wherein the means for displaying detected voltage is a sound indicator.

8. The controller of claim 7, wherein the sound indicator emits different sound tones based on the different detected voltages.

9. The controller of claim 7, wherein the sound indicator emits a different number of sound tones based on the different detected voltages.

10. The controller of claim 1, wherein the means for displaying detected voltage is a display screen.

11. A controller for use with security systems for installation in a vehicle, including remote start security systems, the controller comprising:
a) a housing;
b) means for detecting resistance coupled to the housing; and
c) means for displaying detected resistance coupled to the housing
wherein during the installation of the remote start security system, a user can use the means for detecting resistance to determine the resistance of a vehicle wire, the resistance being displayed on the means for displaying detected resistance.

12. The controller of claim 11, wherein means for detecting resistance is an external probe.

13. The controller of claim 12, wherein the external probe is removably coupled to the housing.

14. The controller of claim 11, wherein the means for displaying detected resistance is a light indicator.

15. The controller of claim 14, wherein the light indicator is a light emitting diode.

16. The controller of claim 14, wherein the light indicator emits different colors of light based on different detected resistances.

17. The controller of claim 11, wherein the means for displaying detected resistance is a sound indicator.

18. The controller of claim 17, wherein the sound indicator emits different sound tones based on different detected resistances.

19. The controller of claim 17, wherein the sound indicator emits a different number of sound tones based on different detected resistances.

20. The controller of claim 11, wherein the means for displaying detected resistance is a display screen.

21. A controller for use with security systems for installation in a vehicle, including remote start security systems, the controller comprising:
a) a housing;
b) means for detecting voltage of vehicle wire coupled to the housing;
c) means for detecting resistance of a vehicle wire coupled to the housing; and
d) means for displaying detected voltage and detected resistance coupled to the housing
wherein during the installation of the remote start security system, a user can use the means for detecting voltage to determine the voltage of a wire and can use the means for detecting resistance to determine the resistance of a wire, with the detected voltage and detected resistance being displayed on the means for displaying detected voltage and detected resistance.

22. The controller of claim 21 further comprising a switch to allow a user to change between different detection states.

23. The controller of claim 22, wherein the different detection states comprise detecting voltage and detecting resistance.

24. The controller of claim 21, wherein the means for detecting voltage of a vehicle wire and the means for detecting resistance of a vehicle wire is an external probe.

25. The controller of claim 24, wherein the external probe is removably coupled to the housing.

26. The controller of claim 21, wherein the means for displaying detected voltage and detected resistance is a light indicator.

27. The controller of claim 21, wherein the means for displaying detected voltage and detected resistance is a sound indicator.

28. The controller of claim 21, wherein the means for displaying detected voltage and detected resistance is a display screen.

29. The controller of claim 28, wherein the display screen is a liquid crystal display.

30. A controller for use with security systems for installation in a vehicle, including remote start security systems, the controller comprising:
a) a housing;
b) means for detecting voltage of a vehicle wire coupled to the housing;
c) means for detecting resistance of a vehicle wire coupled to the housing;
d) means for displaying detected voltage and detected resistance coupled to the housing;
e) a processor; and
f) at least one memory module
wherein during the installation of the remote start security system, a user can use the means for detecting voltage to determine the voltage of a wire and can use the means for detecting resistance to determine the resistance of a wire, with the detected voltage and detected resistance being displayed on the means for displaying detected voltage and detected resistance.

31. The controller of claim 30, wherein means for detecting voltage of a vehicle wire and the means for detecting resistance of a vehicle wire is an external probe.

32. A controller for use with security systems for installation in a vehicle, including remote start security systems, the controller comprising:
a) a housing;
b) an external probe for detecting positive and negative voltage coupled to the housing;
c) means for displaying detected voltage coupled to the housing; and
d) a switch for selecting between the testing of positive voltages and the testing of negative voltages
wherein during the installation of the remote start security system, a user can use the switch to choose between detecting positive voltages and negative voltages, then can use the external probe to determine the voltage of a vehicle wire, with the voltage being displayed on the means for displaying detected voltage.

33. The controller of claim 32, wherein the means for displaying detected voltage and detected resistance is a light indicator.

34. The controller of claim 32, wherein the means for displaying detected voltage and detected resistance is a sound indicator.

35. The controller of claim 32, wherein the means for displaying detected voltage and detected resistance is a display screen.
